(19) United States
(12) Patent Application Publication
(10) Pub. No.: US 2018/0315693 A1
(43) Pub. Date: Nov. 1, 2018

(54) FLIP-CHIP DEVICE AND METHOD FOR PRODUCING A FLIP-CHIP DEVICE

(71) Applicant: Infineon Technologies AG, Neubiberg (DE)

(72) Inventors: Benedikt KINDL, Wackersdorf (DE); Andreas BEER, Regensburg (DE); Uwe WAGNER, Bad Abbach (DE); Philip SEEBAUER, Regensburg (DE); Christian KIESL, Regensburg (DE)

(21) Appl. No.: 15/963,146

(22) Filed: Apr. 26, 2018

(30) Foreign Application Priority Data
Apr. 26, 2017 (DE) 10 2017 108 871.7

(51) Int. Cl. H01L 23/498; H01L 23/00; H01L 21/48

(52) U.S. Cl. CPC H01L 23/49838; H01L 24/16; H01L 24/32; H01L 24/73; H01L 2224/81385; H01L 24/81; H01L 2224/1607; H01L 2224/32225; H01L 2224/73204; H01L 21/4853

(57) ABSTRACT

In various embodiments, a flip-chip device is provided. The flip-chip device includes a chip having an electrically conductive chip contact, and a carrier having an electrically conductive contact area for contacting the chip contact. The chip contact includes a material which is at least just as easily deformable as a material of the electrically conductive contact area at least during the contacting of the chip contact. The contact area includes a plurality of depressions. A smallest width of each of the depressions is smaller than a smallest width of the chip contact. Each of the distances between adjacent edges of adjacent depressions is smaller than the smallest width of the chip contact. The plurality of depressions in the contact area are formed as tubular depressions. A ratio of diameter to depth of the tubular depressions is in a range of 1:3 to 1:50.

### CROSS-REFERENCE TO RELATED APPLICATION

This application claims priority to German Patent Application Serial No. 10 2017 108 871.7, which was filed Apr. 26, 2017, and is incorporated herein by reference in its entirety.

### TECHNICAL FIELD

Various embodiments generally relate to a flip-chip device and a method for producing a flip-chip device.

### BACKGROUND

As is illustrated in FIGS. 1A and 1B, an electrical contacting of chip contacts 126, which can be provided at a first main side of a chip 110, with contact areas 100, which can be arranged on a carrier 112, can be embodied in various cases as so-called flip-chip contacting, in which the chip 110 with its first main side facing the carrier is fitted to the carrier 112 (e.g. pressed thereon to give rise to a pressure contact) in such a way that respectively one of the chip contacts 126 contacts one of the contact areas 100. In this case, the chip 110 can be held in place by means of an adhesion medium 122 arranged between the chip 110 and the carrier 112.

FIG. 1C illustrates an enlarged view of a region A from FIG. 1B. It can be discerned therein that in a region B the chip contact 126 contacts the contact area 100, wherein the physical and electrically conductive contact is formed substantially in a plane as a two-dimensional contact interface (illustrated as a line in cross section in FIG. 1C).

After the flip-chip connection has been produced, it can be subjected to loadings, for example a test of a mechanical robustness during a use of the chip in a smart card. During the test (or possibly even during normal use), the connection of the chip to the carrier or of the chip contact to the contact area can be loaded, which can lead to a deformation of material (e.g. of the adhesion medium 122) and hence to an opening of the contact, as is illustrated in FIG. 1D.

Theoretically, by virtue of the fact that the contact area 100 is provided with a depression 220, into which the chip contact 126 is to be introduced, an attempt can be made (as illustrated in FIG. 2A to FIG. 2D) to prevent an opening of the contact (with an associated loss of electrical conductivity of the contact).

However, manufacturing and positioning tolerances can have the effect that it is difficult actually to arrange the chip contact 126 in the depression 220 of the contact area 100 in such a way as to produce the electrically conductive contact between the chip contact 126 and the contact area 100. This is because owing to a positioning error, for example, the chip contact 126 can be positioned such that the depression 220 is missed (see FIG. 2A and FIG. 2B), and/or the sizes (e.g. diameters) of the chip contact 126 and of the depression 220 can be coordinated with one another so poorly that the chip contact 126 is able to be introduced completely into the depression 220 without an electrically conductive contact being produced (that is to say that the chip contact 126 can be too small for the depression 220, the depression 220 can be too large for the chip contact 126, or both are possible, see FIG. 2C and FIG. 2D, in which the missing contact is represented as a lightning symbol 222). Moreover, in the case where the chip contact 126 sinks completely in the depression 220, a surface of the chip 110 can be damaged if it comes into contact with the carrier surface (illustrated as lightning symbol 224 in FIG. 2D). In this case, the problem can be exasperated by the fact that the chip 110 typically includes more than one chip contact 126, with each of which a dedicated contact area is to be contacted.

### SUMMARY

In various embodiments, a flip-chip device is provided. The flip-chip device includes a chip having an electrically conductive chip contact, and a carrier having an electrically conductive contact area for contacting the chip contact. The chip contact includes a material which is at least just as easily deformable as a material of the electrically conductive contact area at least during the contacting of the chip contact. The contact area includes a plurality of depressions. A smallest width of each of the depressions is smaller than a smallest width of the chip contact. Each of the distances between adjacent edges of adjacent depressions is smaller than the smallest width of the chip contact. The plurality of depressions in the contact area are formed as tubular depressions. A ratio of diameter to depth of the tubular depressions is in a range of 1:3 to 1:50.

### BRIEF DESCRIPTION OF THE DRAWINGS

In the drawings, similar reference signs usually refer to the same parts in all the different views, although for the sake of clarity in some instances not all mutually corresponding parts in all figures have been provided with reference signs. For differentiation, parts of the same or similar type may be provided with an attached digit or an attached letter in addition to a common reference sign (e.g. the contact area 332 with various embodiments 332a, 332b, 332c, 332d, 332e, 332f and 332g). The drawings are not necessarily intended to represent a true-to-scale reproduction, rather the emphasis is on illustrating the principles of the invention. In the following description, various embodiments of the invention are described with reference to the following drawings, in which:

FIG. 1A shows a schematic cross-sectional view of a conventional flip-chip device before production of a contact between chip contacts of a chip and contact areas of a carrier;

FIG. 1B shows a schematic cross-sectional view of the flip-chip device from FIG. 1A after the production of the contact between the chip contacts of the chip and the contact areas of the carrier;

FIG. 1C shows an enlarged illustration of the region A from FIG. 1B;

FIG. 1D shows the region A from FIG. 1B and FIG. 1C after a loss of contact between the chip contact and the contact area;

FIG. 2A shows a schematic plan view of parts of one exemplary flip-chip device;

FIG. 2B shows a schematic cross-sectional view of the flip-chip device from FIG. 2A;

FIG. 2C shows a schematic plan view of parts of a conventional flip-chip device;

FIG. 2D shows a schematic cross-sectional view of the flip-chip device from FIG. 2C;

FIG. 3A shows a schematic plan view of a flip-chip device in accordance with various embodiments;

FIG. 3B shows a schematic cross-sectional view of the flip-chip device from FIG. 3A;

FIG. 3C shows a schematic cross-sectional view of a flip-chip device in accordance with various embodiments;

FIG. 4A to FIG. 4D show in each case a schematic plan view of parts of a flip-chip device in accordance with various embodiments;

FIG. 4E shows a schematic cross-sectional view of a flip-chip device in accordance with various embodiments together with an enlarged plan view of a contact area of the flip-chip device;

FIG. 5A and 5B show in each case a schematic plan view of parts of a flip-chip device in accordance with various embodiments;

FIG. 6A and FIG. 6B show in each case a schematic cross-sectional view of a flip-chip device in accordance with various embodiments;

FIG. 7A shows a schematic plan view of parts of a conventional flip-chip device;

FIG. 7B shows a schematic plan view of parts of a flip-chip device in accordance with various embodiments; and

FIG. 8 shows a flow diagram of a method for forming a flip-chip device in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “above” used with reference to a deposited material formed “above” a side or surface may be used herein with the meaning that the deposited material can be formed “directly thereon”, i.e. in direct contact with the indicated side or surface. The word “above” with reference to a deposited material formed “above” a side or surface may be used herein with the meaning that the deposited material can be formed “directly on” the indicated side or surface with one or more additional layers arranged between the indicated side or surface and the deposited material.

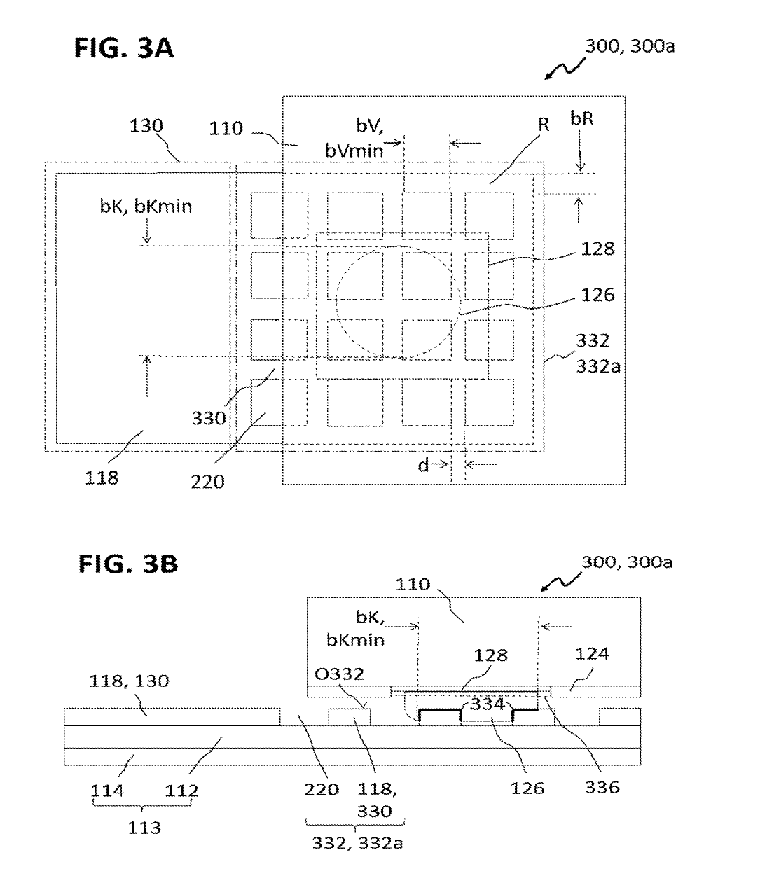

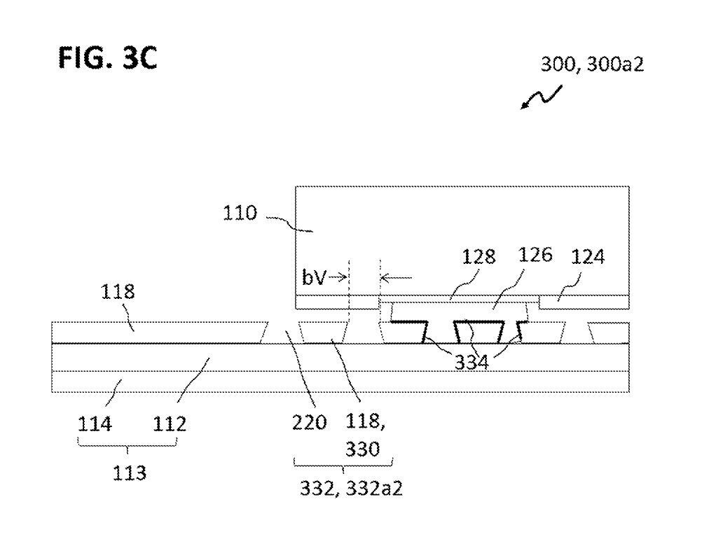

FIG. 3A shows a schematic plan view of a flip-chip device 300, 300a in accordance with various embodiments, and FIG. 3B shows a schematic cross-sectional view of the flip-chip device 300, 300a from FIG. 3A.

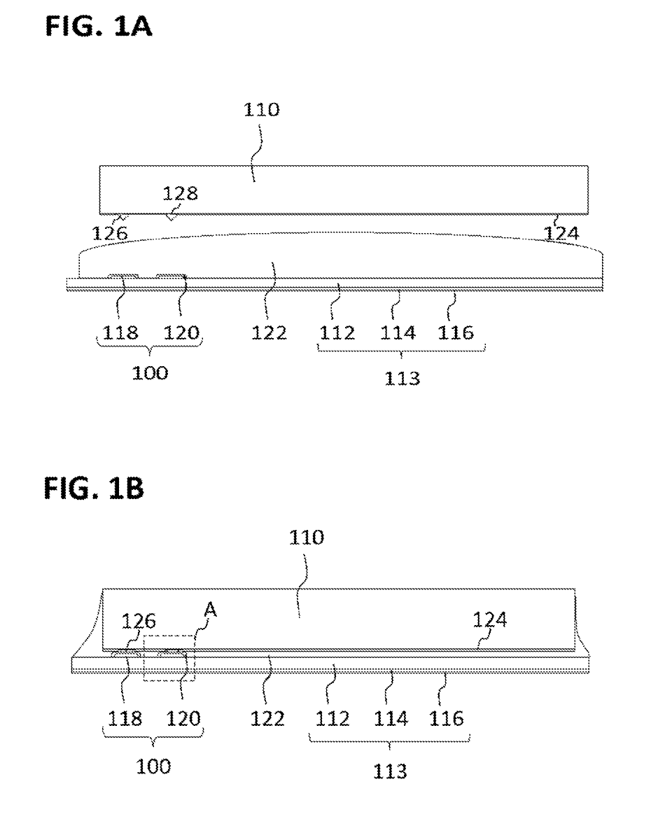

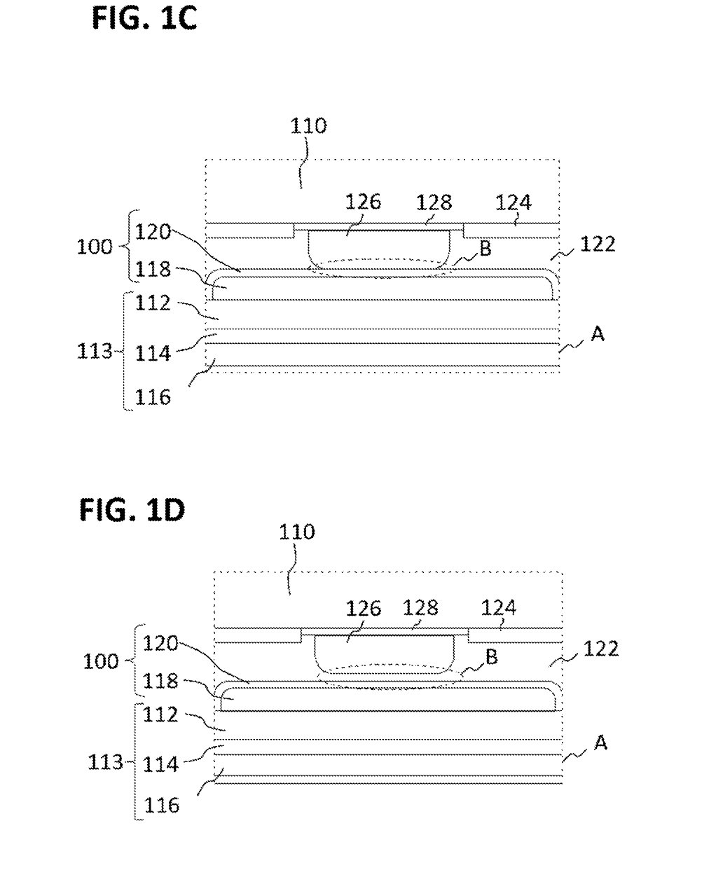

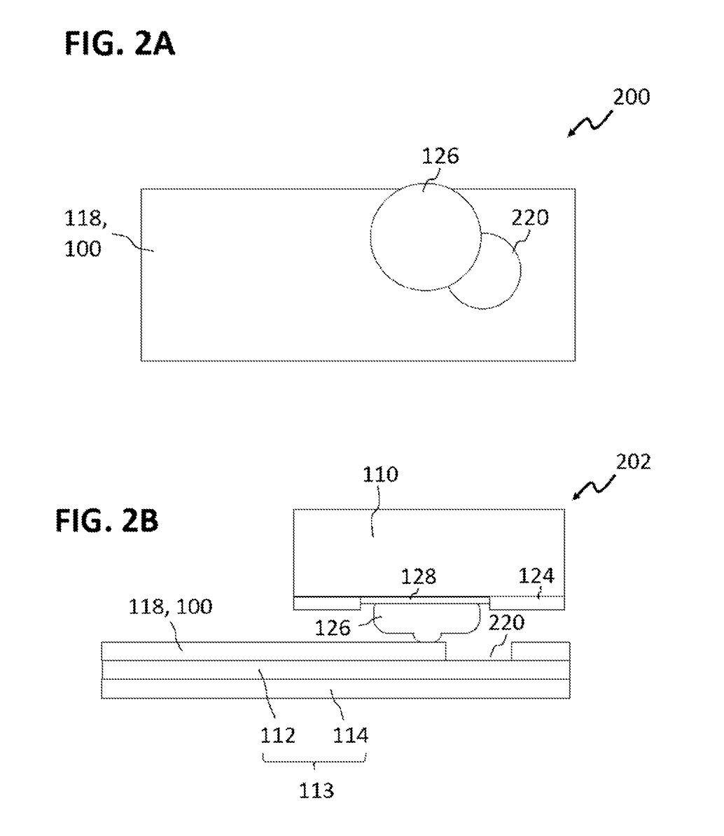

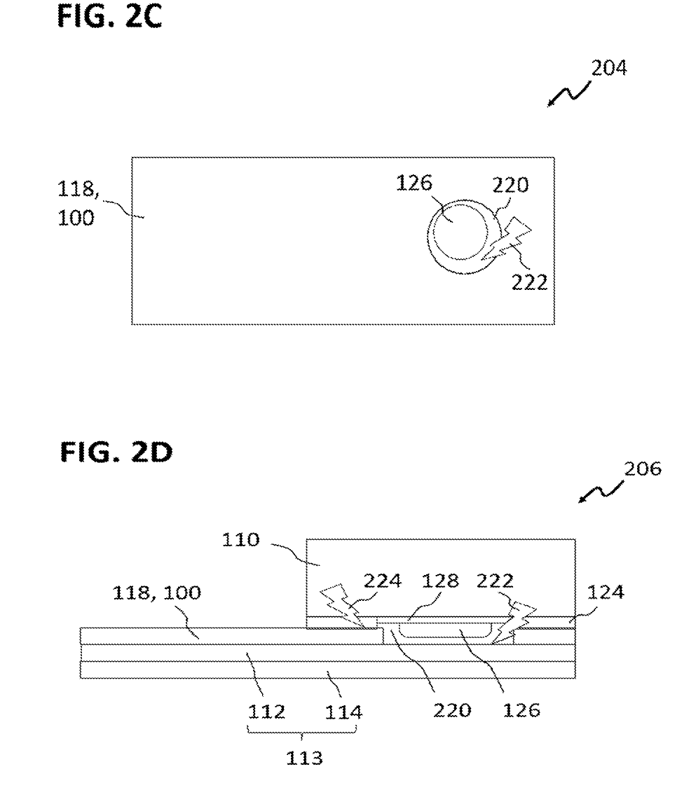

Various elements, dimensions, materials, production methods, etc. of the flip-chip device 300, 300a may be similar or identical to those of a conventional flip-chip device, for example the conventional flip-chip device from FIG. 1A to FIG. 1D, FIG. 2A and/or FIG. 2B. In the figures, said elements may be provided with the same reference signs.

As is illustrated in FIG. 3A and FIG. 3B, the flip-chip device 300, 300a may include a chip 110, e.g. a semiconductor chip, having an electrically conductive chip contact 126 and a carrier 113 having an electrically conductive contact area 332, 332a for contacting the chip contact 126, wherein the chip contact 126 may include a material which can be at least just as easily deformable as a material of the electrically conductive contact area 332, 332a (e.g. more easily deformable than the material of the contact area 332) at least during the contacting of the chip contact 126, wherein the contact area 332, 332a may include a plurality of depressions 220, wherein a smallest width bVmin of each of the depressions 220 is smaller than a smallest width bKmin of the chip contact 126, and wherein a distance d between adjacent edges of adjacent depressions 220 is in each case smaller than the smallest width bKmin of the chip contact 126.

In various embodiments, the carrier 113 can be formed as described above, e.g. it may include an electrically insulating material. In various embodiments, the carrier 113 may include a printed circuit board, e.g. a body of a smart card module. In various embodiments, the carrier 113 may include for example an electrically insulating layer 112 (e.g. a carrier layer), e.g. a plastics or ceramic layer. In various embodiments, the carrier 113 can additionally include at least one electrically conductive layer 114. In various embodiments, the electrically conductive layer 114 may include the same material as the contact area 332, 332a, and/or some other electrically conductive material.

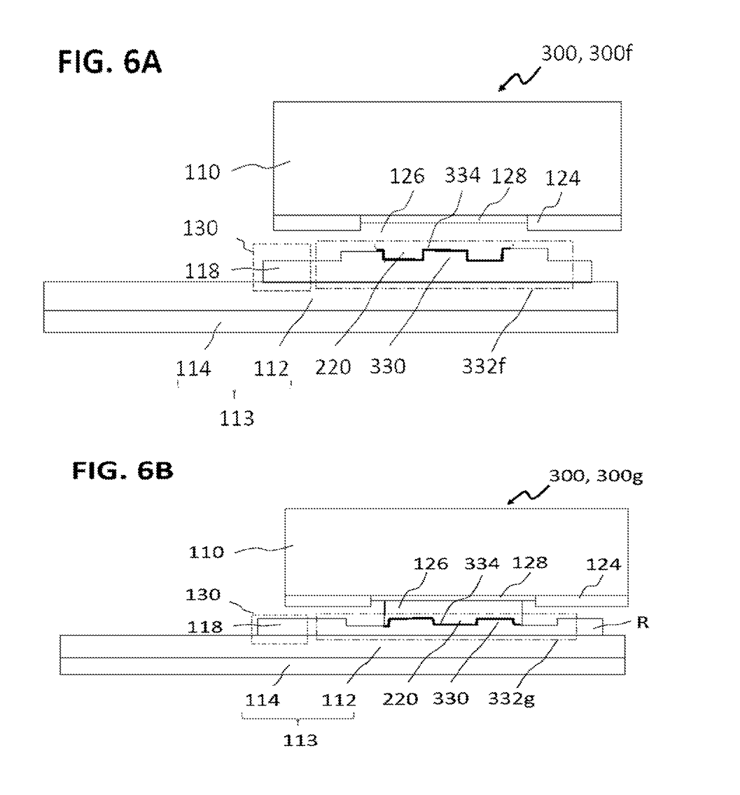

In various embodiments, the electrically conductive contact area 332, 332a may include a first side facing the carrier 113 and a second side situated opposite the first side, and the plurality of depressions 220 can extend completely (as illustrated in FIG. 3B) or only partly (as illustrated in FIG. 6A and FIG. 6B) from the second side as far as the first side. In a case where the depression 220 extends only partly as far as the first side, conductive material may still remain between a bottom of the depression and the carrier.

In various embodiments, forming the electrically conductive contact area 332, 332a having the plurality of depressions 220 can substantially be performed by means of known methods for producing structured electrically conductive layers, for example as described above, e.g. by means of forming an electrically conductive layer followed by removing those parts of the electrically conductive layer which are situated where the depressions 220 are to be arranged, or e.g. by means of directly forming the electrically conductive contact area 332, 332a provided with the depressions 220.

In various embodiments, the chip contact 126 can substantially be formed in a known manner, for example with a conventional shape and a conventional material, provided that the requirements described herein in respect of shape and material with regard to the contact area 332 are satisfied, that is to say that the minimum width bKmin of the chip contact 126 is larger than the minimum width bVmin of the plurality of depressions 220 and larger than the distance d between adjacent edges of adjacent depressions 220, and that the material of the chip contact 126 includes an electrically conductive material which is at least just as easily deformable as a material of the electrically conductive contact area 332, e.g. more easily deformable than the material of the contact area 332, at least during the contacting of the chip contact 126. In various embodiments, the chip contact 126 may include the materials described above. In various embodiments, the minimum width bKmin of the chip contact 126 can be in a range from approximately 20 μm to approximately 120 μm, e.g. from approximately 30 μm to approximately 100 μm, e.g. around approximately 70 μm. A thickness of the chip contact can be in a range of approximately 10 μm to approximately 70 μm, e.g. of approximately 20 μm to approximately 50 μm. In various embodiments, electrically conductive material 128, e.g. as a contact pad, e.g. as an aluminum contact pad, can be arranged between the chip contact 126 and the chip 110. In various embodiments, other surface regions of the chip 110, e.g. surface regions facing the carrier 113, can be provided with a passivation layer 124, e.g. a polyimide passivation layer.

During the production of the pressure contacting between the chip contact 126 and the contact area 332 (e.g. by means of the chip 110 and the carrier 113 being pressed onto one another in such a way that the chip contact 126 and the contact area 332 come into contact with one another and the chip contact 126 deforms, if appropriate by means of additional heating as described above), the chip contact 126 can thus be deformed on the contact area 332 and into the depression(s) 220 in order to form the three-dimensionally structured contact interface 334, the cross section of which is illustrated as a bold line in FIG. 3B, FIG. 3C, FIG. 6A and FIG. 6B. Depending on how the contact area 332 is configured and how the chip contact 126 deforms, the contact interface 334 can be shaped differently.

In various embodiments, the contact interface 334 can form a single contiguous whole-area region. This is e.g. the case in the embodiments illustrated in FIG. 6A and FIG. 6B, in which the chip contact 126 has deformed in such a way that it is in contact both with the electrically conductive material between the depressions 220 and with the electrically conductive material at the bottom of the depressions 220.

In various embodiments, the contact interface 334 can form a contiguous but not whole-area region. This is e.g. the case in the embodiment illustrated in FIG. 3B, in which the chip contact 126 has deformed in such a way that it is in contact with the electrically conductive material between the depressions 220, which is configured as a lattice, such that it has a ring-shaped region around each of the depressions 220, but said chip contact is in contact with no conductive material at a chip contact underside facing the carrier.

In various embodiments, the contact interface 334 can form a plurality of separate contact interface regions, e.g. in a case (not illustrated) where the contact area 332 is structured in such a way that the electrically conductive material between adjacent depressions 220 is formed in a columnar fashion and the depressions 220 do not extend as far as the first side, such that the individual columnar regions of electrically conductive material are electrically conductively connected to one another by means of electrically conductive material remaining at the bottom of the depressions, but the chip contact 126 does not extend as far as the bottom of the depressions 220 after the contacting/deforming.

In various embodiments, the contact area 332 can be so rigid that it does not deform or deforms only insignificantly during the production of the pressure contacting, even in a case where the chip contact 126 (and possibly likewise the contact area 332) is heated.

In various embodiments, the contact area may include an electrically conductive material as described above.

In various embodiments, the chip contact 126 and the contact area 332 may include different materials, e.g. materials which are (e.g. plastically) deformable to different extents, wherein the chip contact 126 may include the material having the better (higher) deformability. By way of example, if the contact area 332 includes a usually relatively rigid copper alloy as the electrically conductive material or the material consists thereof, the chip contact 126 may include or essentially consist of gold, which, compared with the copper alloy, can be deformable relatively easily. By contrast, if a contact area 332 composed of/ including gold is used, for example, the chip contact 126 may include the silver alloy solder, for example, which can be more easily deformable than the gold at least at a soldering temperature.

In various embodiments, that (area) region of the flip-chip device which consists of the plurality of depressions 220 and the electrically conductive material 118 arranged between the depressions 220 can be referred to as the contact area 332. The electrically conductive material 118 arranged between the depressions 220 or in a manner adjoining the depressions 220 is provided with the reference sign 330 in FIG. 3A to FIG. 6B. In various embodiments, an edge area region R which at least partly (e.g. completely) surrounds the region with the depressions 220 and the electrically conductive material 118 arranged therebetween and which can have a smaller width bR than the smallest width bKmin of the chip contact can furthermore be regarded as associated with the contact area 332.

In various embodiments, the plurality of depressions 220 can be arranged in such a way as to fill the contact area 332. To put it another way, the plurality of depressions 220 can be arranged in a manner distributed over the entire contact area 332, together with the electrically conductive material 118 arranged in each case between the depressions 220 and demarcating the respective depressions 220 relative to one another (and, if appropriate, in various embodiments, together with the edge region R composed of the electrically conductive material 118 that at least partly surrounds the plurality of depressions overall).

A conduction region 130 which is electrically conductively connected to the contact area 332, e.g. adjoins the contact area 332, and which includes none of the depressions 220 and is also not part of the edge region R can, in various embodiments, not be part of the contact area 332.

In various embodiments, the contact area may include a topmost surface O332, which should be understood to mean a surface region which is at a maximum distance from the carrier 113 (wherein the distance is measured in a direction perpendicular to a main area of the carrier 113). The plurality of depressions 220 can be formed in the contact area 332 in such a way that each of the depressions 220 extends from the topmost surface O332 in a direction toward the carrier 113. The respective depression 220 can extend partly or completely as far as the carrier. A depth of the depression can be between approximately 5 μm and approximately 50 μm, for example between approximately 10% and 100% of the thickness of the contact area 332.

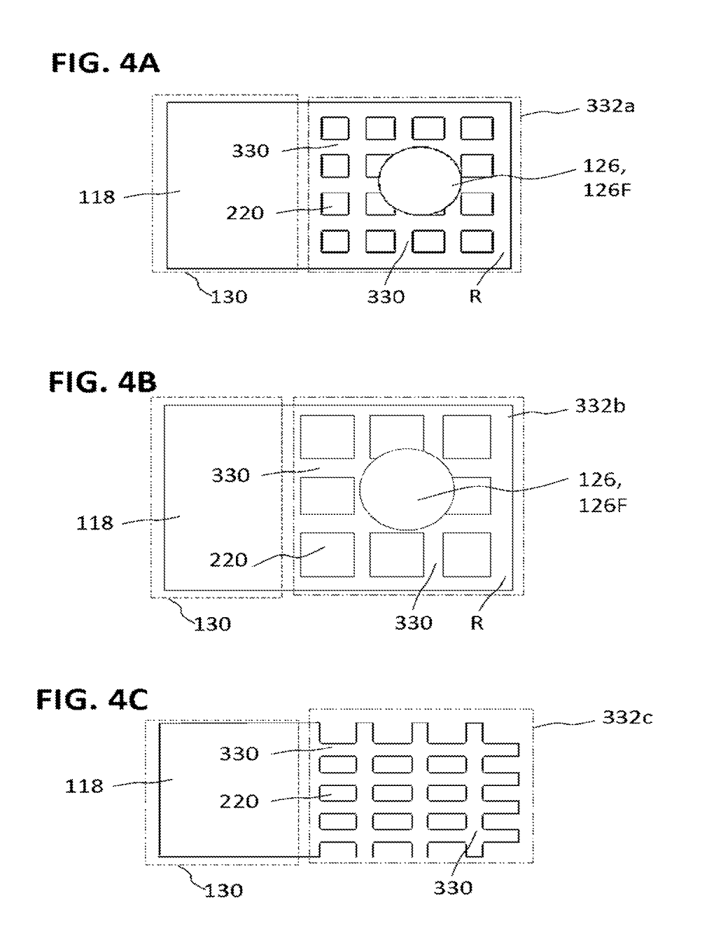

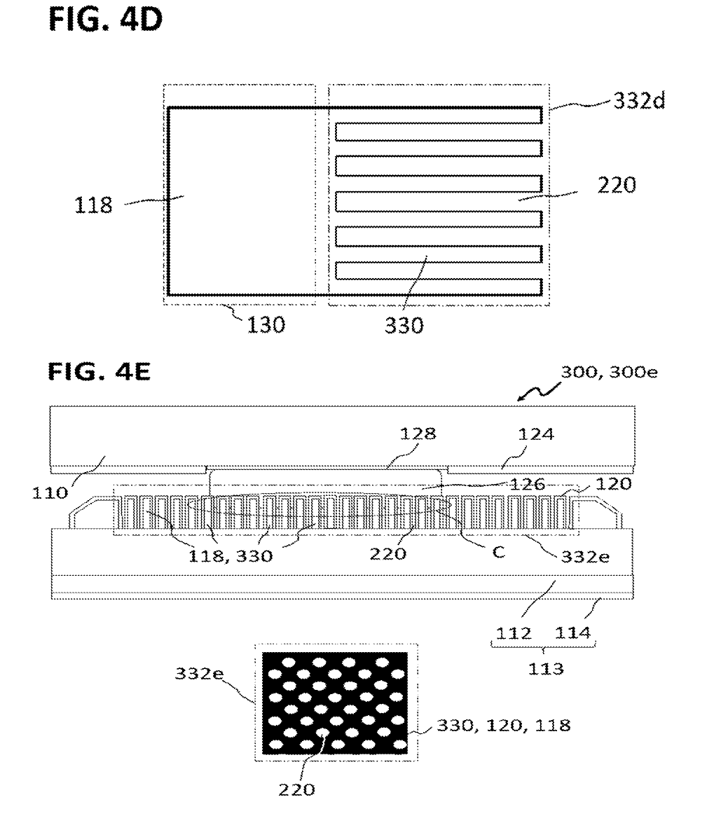

In various embodiments, a width bV of the depression 220 should be understood to mean any distance between mutually opposite edges of the depression 220, wherein the distance is measured parallel to a main area of the carrier 113. The smallest width bVmin of the depression 220 is that width bV of the depression 220 for which the mutually opposite edges have the smallest distance. In a case where the mutually opposite edges of the depression have the same distance everywhere (e.g. in the case of a depression 220 having a circular cross section, as illustrated e.g. in FIG. 4E), the width bV of the depression 220 is also simultaneously the smallest width bVmin.

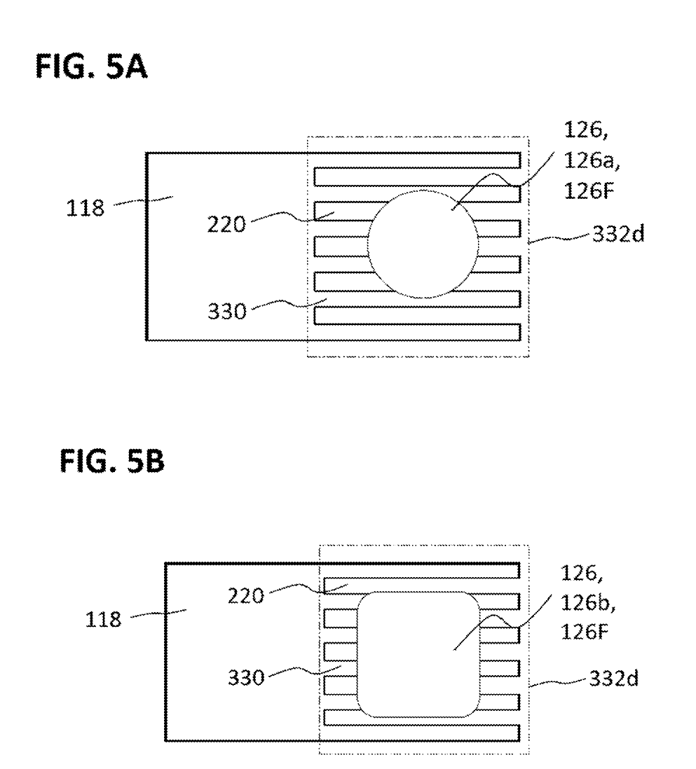

Correspondingly, a width bK of the chip contact 126 should be understood to mean any distance between mutually opposite edges of the chip contact 126, wherein the distance is measured parallel to a main area of the chip 110. The smallest width bKmin of the chip contact 126 is that width bK of the chip contact 126 for which the mutually opposite edges have the smallest distance. In a case where the mutually opposite edges of the chip contact 126 have the same distance everywhere (e.g. in the case of a chip contact 126 having a circular cross section, as illustrated e.g. in FIG. 3A, FIG. 4A, FIG. 4B and FIG. 5A), the width bK of the chip contact 126 is also simultaneously the smallest width bKmin.

Since, in each of the depressions 220, the smallest width bVmin is smaller than the smallest width bKmin of the chip contact 126, it is possible, in various embodiments, to prevent the chip contact 126 from being able to be arranged in the depression 220 completely, without producing an electrically conductive contact.

In various embodiments, a distance d between adjacent edges of adjacent depressions 220 can in each case be smaller than the smallest width bKmin of the chip contact 126. To put it another way, a region of the topmost surface 0332 that is situated between respectively two adjacent depressions 220 can have a smaller width d than the smallest width bKmin of the chip contact 126. This makes it possible to prevent the chip contact 126 from being arranged only on the topmost surface O332, which would lead to a two-dimensional contact interface formed in a plane (as illustrated in FIG. 1C and FIG. 1D). By virtue of the fact that the region between two adjacent depressions 220 is narrower than the chip contact 126, irrespective of where on the contact area 332 the chip contact 126 is arranged, the chip contact 126 is always pressed into at least one of the depressions 220 at least partly during the production of the press contact, thus resulting in the three-dimensional structure of the contact interface 334.

In various embodiments (see e.g. FIG. 4A, FIG. 4B, FIG. 5A and/or FIG. 5B), the contact area 332 can be larger than a cross-sectional area 126F of the chip contact 126 parallel to a main area of the chip 110. In a case where the chip contact 126 has a shape that tapers toward the chip 110 or away from the chip 110, the contact area 332 can be larger than the largest cross-sectional area 126F of the chip contact 126 parallel to the main area of the chip 110. FIG. 3B indicates as a line 336 where the cross-sectional area 126F can be determined in the case of a tapering chip contact 126, namely where the cross-sectional area 126F parallel to the main area of the chip 110 is the largest.

Thus, in various embodiments, a relatively large positioning tolerance can be made possible since, given the presence of the contact area 332 which is larger than the cross-sectional area 126F of the chip contact 126, the chip contact 126 can be reliably connectable to the contact area 332 even in the event of a deviation from its nominal position during the production of the pressure contact.

In various embodiments, the contact area 332 can be between approximately 1.1 and approximately ten times the size of the cross-sectional area 126F of the chip contact 126, e.g. between two and five times the size thereof.

In various embodiments, the contact area 332 can be enlarged uniformly in every direction, compared with the cross-sectional area 126F of the chip contact 126. This is illustrated by way of example in FIG. 5B for a chip contact 126b having a (substantially) square cross section and a contact area 332d which is likewise (substantially) square, with a larger edge length.

In various embodiments, the contact area 332 can be enlarged non-uniformly in different directions, compared with the cross-sectional area 126F of the chip contact 126, as is illustrated by way of example in FIG. 3A, FIG. 4A, FIG. 4B and FIG. 5A for a chip contact 126 having a round or substantially round cross-sectional area and a (substantially) square contact area, such that the contact area 332 can be enlarged to a greater extent in a direction toward the corners of the contact area 332 with respect to the round chip contact 126.

In various embodiments, the contact area 332 can have a minimum width in a range of approximately 100 μm to approximately 200 μm, e.g. of approximately 120 μm to approximately 200 μm.

FIG. 3C shows a schematic cross-sectional view of a flip-chip device 300a2 in accordance with various embodiments.

Various elements, dimensions, materials, production methods, etc. of the flip-chip device 300, 300a2 may be similar or identical to those of the flip-chip device 300a.

In contrast to the flip-chip device 300a, the plurality of depressions 220 in the contact area 332a2 of the flip-chip device 300a2 can be configured in such a way that they have a trapezoidal cross section, wherein a base of the trapezoid can face the carrier 113. That means that a width bV of the depression 220 increases from the topmost surface O332 in the direction toward the carrier 113. In that case, the minimum width bV of the depression 220 can be that width bV at which respective partial regions (e.g. upper edges) of opposite edges of the depression 220 have the smallest distance.

In various embodiments, the chip 110 and the carrier 113 can be pressed together in such a way that the chip contact 126 reaches the bottom of the depressions 220 and then still further pressure is exerted on the chip 110 and the carrier 113 in order to press them against one another, such that the plastically deformable chip contact 126 spreads into a region of the depression which is covered by the electrically conductive material 118 of the contact area 332 in a direction toward the chip, that is to say that the chip contact 126 partly extends to below the electrically conductive material 118 of the contact area 332 after deformation.

In various embodiments, the depressions 220 can be provided independently of their cross-sectional shape parallel to the surface of the carrier 113 as depressions 220 with the trapezoidal cross section.

The depressions 220 with the trapezoidal cross section can enable the production of a positively locking engagement between the chip contact 126 that is deformed after the contacting (and if appropriate solidified again) and the contact area 332a2, which positively locking engagement can additionally be suitable for preventing a contact loss of the contact between the contact area 332a2 and the chip contact 126.

In various embodiments (not illustrated), the plurality of depressions 220 in the contact area 332 of the flip-chip device 300 can be configured in such a way that they have a trapezoidal cross section, wherein a base of the trapezoid can face away from the carrier 113. That means that a width bV of the depression 220 decreases from the topmost surface O332 in a direction toward the carrier 113. In that case, the maximum width bV of the depression 220 can be that width bV at which respective partial regions (e.g. upper edges) of opposite edges of the depression 220 have the smallest distance.

In various embodiments, sidewalls of the depressions 220 can be configured in such a way that they neither extend perpendicularly or substantially perpendicularly to a main area of the carrier (as illustrated for example in FIG. 3B, FIG. 4E, FIG. 6A and FIG. 6B) nor extend as a planar area obliquely with respect to a main area of the carrier (as illustrated by way of example in FIG. 3C for the depression with the trapezoidal cross section), but rather are configured as a substantially arbitrarily shaped area. The sidewalls of the depressions 220 can be configured for example in such a way that the depressions 220 have a mushroom-shaped, barrel-shaped or cushion-shaped cross section (not illustrated).

FIG. 4A to FIG. 4D show in each case a schematic plan view of parts of a flip-chip device in accordance with various embodiments, more precisely of the contact area 332a, 332b, 332c and 332d, respectively, with a respective adjacent conduction region 130 (and in FIG. 4A and FIG. 4B the chip contact 126).

FIG. 4A shows the lattice-shaped contact area 332a from FIG. 3A, in which square depressions 220 are arranged as a two-dimensional matrix, such that the electrically conductive material 118 remaining between the depressions 220 has a lattice-shaped structure. The contact area 332a furthermore has an edge region R. In a horizontal and a vertical direction, the contact area 332a (which is approximately square) is in each case approximately twice as wide as the width of the chip contact 126. Thus, in various embodiments, this can achieve the effect that, given an arbitrary positioning of the chip contact 126 on the contact area 332a, the chip contact 126 is always arranged above at least one of the depressions 220 and the electrically conductive material 118 arranged therebetween, such that the chip contact 126 deforms during the production of the pressure contact in such a way that a three-dimensional contact interface is formed between the chip contact 126 and the contact area 332a, as described above.

In various embodiments, the contact area 332a structured in a lattice-like fashion can also be formed such that electrically conductive material 118 remains in each case at the bottom of the depressions 220, that is to say that the depression 220 is formed in such a way that it does not extend as far as the carrier 113.

FIG. 4B shows a lattice-shaped contact area 332b similar to the contact area 332a and including fewer depressions 220 with the contact area 332b having approximately the same size. Each of the approximately square depressions 220 of the contact area 332b is larger than the approximately square depressions of the contact area 332a.

FIG. 4C shows a contact area 332c, in which rectangular depressions 220 are arranged as a two-dimensional matrix, such that the electrically conductive material 118 remaining between the depressions 220 has a lattice-shaped structure. In contrast to the contact areas 332a and 332b, the contact area 332c has an edge only in a direction toward the conduction region 130.

FIG. 4D shows a contact area 332d, in which rectangular, elongated depressions 220 are arranged parallel to one another, in a manner offset perpendicularly to their respective longitudinal axes, in such a way that the electrically conductive material 118 remaining between the depressions 220 has a comb-like structure. In contrast to the contact areas 332a and 332b, the contact area 332d has an edge only at three sides (in a direction toward the conduction region 130 and at two sides, whereas that side of the contact area 332d which faces away from the conduction region 130 has no edge).

FIG. 4E shows a schematic cross-sectional view of a flip-chip device 300e in accordance with various embodiments in an upper illustration, and an enlarged plan view of a contact area 332e of the flip-chip device 300e in a lower illustration. The region illustrated in an enlarged view is identified by “C” in the upper illustration.

The flip-chip device 300e can substantially correspond to the flip-chip devices 300a and 300a2.

In various embodiments, e.g. in the case of the flip-chip devices 300a and 300a2 or in the case of other flip-chip devices 300, in the case of the contact area 332e the depressions 220 can be formed by means of a laser, e.g. by means of laser ablation. In various embodiments, as illustrated in FIG. 4E, the depressions 220 can be configured as a regular pattern, e.g. by virtue of the depressions 220 being arranged as a two-dimensional matrix. In various embodiments, the depressions 220 can be formed as some other regular pattern or as an irregular pattern.

In various embodiments, forming the depressions 220 by means of a laser can be used to form tubular depressions 220 having a small diameter in comparison with their length. By way of example, a ratio of diameter to depth of the tubular depressions 220 can be in a range of approximately 1:3 to approximately 1:50, e.g. of approximately 1:10 to approximately 1:25. In various embodiments, shallow depressions can also be formed by means of the laser, with a ratio of diameter to depth that is greater than 1:3, for example even 1:1 or more.

The contact areas 332a, 332b, 332c, 332d and 332e illustrated in FIG. 4A to FIG. 4E form contact area configurations in which the depressions 220 are formed as a regular pattern.

FIG. 5A and 5B show in each case a schematic plan view of parts of a flip-chip device in accordance with various embodiments.

Here together with the contact area 332d from FIG. 4D the illustration shows by way of example that a cross-sectional area of the chip contact 126 can have a round shape, as illustrated for the chip contact 126a in FIG. 5A, or a rounded-square shape, as illustrated for the chip contact 126b in FIG. 5B.

In various embodiments, the chip contact 126 can have any arbitrary other expedient shape, provided that the boundary conditions regarding width in comparison with the depressions 220 and the distances between the depressions 220 are satisfied, that is to say that with regard to the relative dimensions and arrangements it is ensured that in the case of a positioning of the chip contact 126 somewhere on the contact area 332 during the production of the pressure contact the three-dimensionally structured contact interface 334 is formed by means of the chip contact 126 partly sinking into at least one of the depressions 220.

FIG. 6A and FIG. 6B show in each case a schematic cross-sectional view of a flip-chip device 300f and 300g, respectively, in accordance with various embodiments.

The flip-chip devices 300f and 300g, respectively, can substantially correspond to the flip-chip devices 300a, 300a2 and/or 300e.

In the case of the flip-chip devices 300f and 300g, respectively, as is illustrated in FIG. 6A and FIG. 6B, in accordance with various embodiments, the plurality of depressions 220 can be formed in such a way that they do not extend as far as the carrier 113, rather electrically conductive material 118 still remains between the respective depression 220 and the carrier 113, e.g. as described above. To put it another way, the electrically conductive material 118 can be formed or arranged in a stepped fashion.

In various embodiments, a configuration of the contact area 332 with regard to electrically conductive material 118 remaining at the bottom of the depressions 220, i.e. between a respective depression 220 and the carrier 113, can be chosen substantially independently of some other configuration and/or arrangement of the plurality of depressions 220. That is to say that, for substantially any shape of the cross-sectional area of the depressions 220 parallel and/or perpendicular to a main area of the carrier 113, the electrically conductive material 118 can be arranged such that electrically conductive material 118 remains in at least one of the depressions 220 and/or be arranged such that at least one of the depressions 220 extends as far as the carrier 113, i.e. no electrically conductive material 118 remains between the depression 220 and the carrier 113.

In various embodiments, all the depressions 220 can be configured in an identical fashion with regard to electrically conductive material 118 remaining between the depression 220 and the carrier 113, that is to say that either all the depressions 220 may include the remaining electrically conductive material 118 between the depression 220 and the carrier 113, or none of the depressions 220 may include the electrically conductive material 118 between the depression 220 and the carrier 113.

In various embodiments, all the depressions 220 can be configured differently with regard to electrically conductive material 118 remaining between the depression 220 and the carrier 113, that is to say at least one of the depressions 220 may include the remaining electrically conductive material 118 between the depression 220 and the carrier 113, and at least one of the depressions 220 may include no electrically conductive material 118 between the depression 220 and the carrier 113.

In various embodiments, in the case of a configuration of the depressions 220 in such a way that they are configured in a manner merging into one another and the electrically conductive material 118 arranged between the depressions 220 is arranged for example as individual projections, at least between a portion of the depressions 220 and the carrier the electrically conductive material 118 can be arranged in such a way that each of the individual projections is electrically conductively connected to the rest of the electrically conductive material 118 of the contact area 332.

In the case of the flip-chip device 300g, the contact area 332g, in contrast to the contact area 332f of the flip-chip device 300f, can have an edge R on a side of the contact area 332g facing away from the conduction region 130.

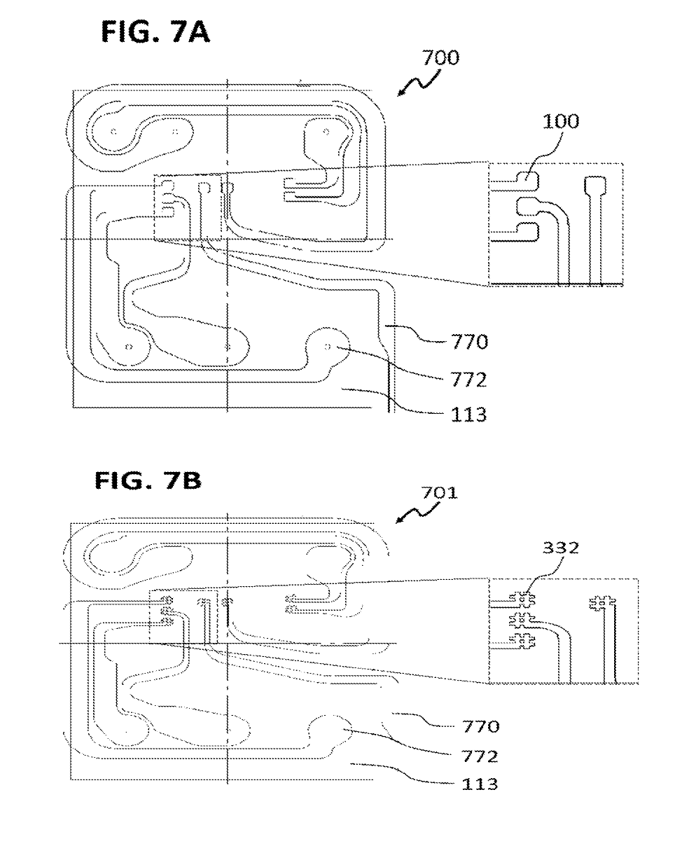

FIG. 7A shows a schematic plan view of parts of a conventional flip-chip device 700.

The conventional flip-chip device 700 may include a carrier 113, conductor tracks 770, electrically conductive plated-through holes 772, which can extend from one side of the carrier 113 through the carrier 113 to the other side of the carrier 113, and a plurality of conventional contact areas 100 (which are additionally shown in even greater detail in an enlarged illustration).

FIG. 7B shows a schematic plan view of parts of a flip-chip device 701 in accordance with various embodiments.

The flip-chip device 701 can substantially be formed like the conventional flip-chip device 700, with the difference that, instead of the conventional contact areas 100, it includes a plurality of contact areas 332 which can be formed in accordance with various embodiments, e.g. as described above. The contact areas illustrated in FIG. 7B can be formed for example in a similar manner to the contact area 332c illustrated in FIG. 4C.

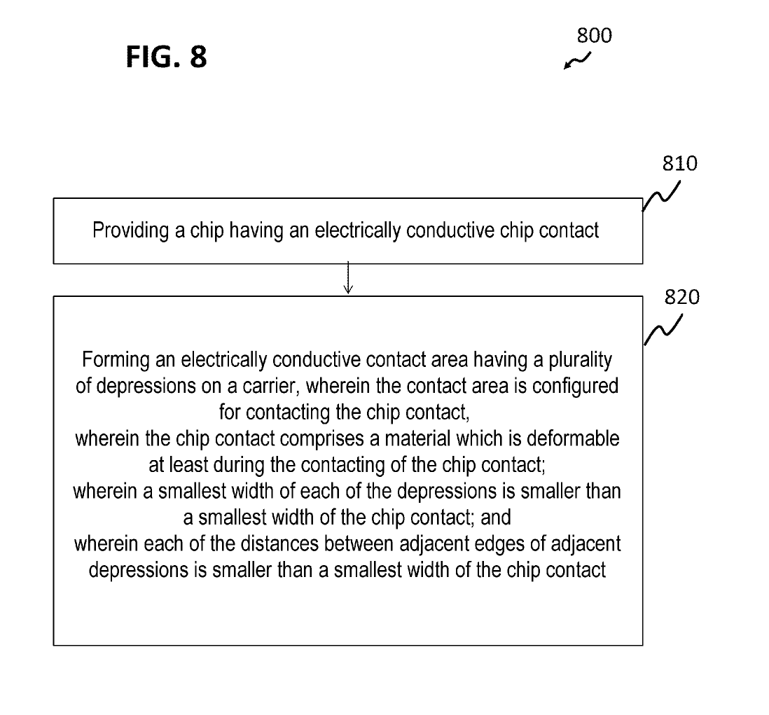

FIG. 8 shows a flow diagram of a method 800 for forming a flip-chip device in accordance with various embodiments.

In various embodiments, the method 800 may include providing a chip having an electrically conductive chip contact (at 810), and forming an electrically conductive contact area having a plurality of depressions on a carrier, wherein the contact area is configured for contacting the chip contact, wherein the chip contact includes a material which is deformable at least during the contacting of the chip contact, wherein a smallest width of each of the depressions is smaller than a smallest width of the chip contact, and wherein each of the distances between adjacent edges of adjacent depressions is smaller than a smallest width of the chip contact (at 820).

In various embodiments, a flip-chip device may be provided which makes it possible to produce a reliable contacting between a chip contact of a chip and a contact area of a carrier despite relatively high manufacturing and positioning tolerances.

In various embodiments, the contact area can be structured by means of a plurality of depressions in such a way that, upon the production of a pressure contacting between the chip contact and the contact area, the chip contact always partly deforms into at least one of the plurality of depressions and is in contact with the contact area partly outside the plurality of depressions, independently of where exactly on the contact area the chip contact is positioned. This can result in a three-dimensional contact interface between the chip contact and the contact area. Even in a case in which the chip contact (e.g. together with the chip) lifts off slightly from the contact area, this will typically be associated with a slight tilting of the chip contact and the contact area relative to one another, which owing to the three-dimensional configuration of the contact interface(s) has the effect that typically even in the slightly lifted-off, tilted position the contact area and the chip contact remain or come into contact at at least one location, with the result that the electrically conductive connection is maintained.

In various embodiments, requirements in respect of a manufacturing tolerance and a positioning accuracy during the production of a reliable flip-chip device can be low.

In various embodiments, it can be ensured that a distance remains between the chip and the carrier, with the result that damage to the chip during the production of the contact can be avoided and moreover a space can remain between the chip and the carrier, in which space it is possible for the adhesion medium to have been arranged or to be arranged, with the result that a reliable securing of the chip to the carrier can be ensured.

In various embodiments, a flip-chip device is provided which may include a chip having an electrically conductive chip contact and a carrier having an electrically conductive contact area for contacting the chip contact, wherein the chip contact may include a material which is more easily deformable than a material of the electrically conductive contact area at least during the contacting of the chip contact, wherein the contact area may include a plurality of depressions, wherein a smallest width of each of the depressions can be smaller than a smallest width of the chip contact, and wherein each of the distances between adjacent edges of adjacent depressions can be smaller than the smallest width of the chip contact.

In various embodiments, each of the depressions can be delimited by at least two mutually opposite edges (and/or regions of edges) of electrically conductive material of the contact area, for example by three, four or more edges (and/or regions of edges) or a circumferential edge.

In various embodiments, the plurality of depressions (and thus also the electrically conductive material arranged between the depressions) can have any arbitrary expedient shape provided that the above boundary conditions with regard to the widths are satisfied. By way of example, the depressions can have a square, rectangular, differently polygonally shaped, round, elliptic, or other cross section. In various embodiments, the electrically conductive material between the depressions can be configured in a lattice-shaped fashion, in a honeycomb-shaped fashion, as a perforated area or as an electrically conductive area having projections (having a cross section of arbitrary shape), which can be electrically conductively connected to one another by means of the electrically conductive area at the bottom of the depressions, or in any other expedient shape that satisfies the stated boundary conditions with regard to widths, etc. In the various embodiments in which the area has the projections, the plurality of depressions can be formed in such a way that they are connected to one another.

In various embodiments, the carrier may include an electrically insulating material, e.g. a plastic (e.g. polyethylene terephthalate or polyimide) or a ceramic material. The carrier can be formed as or include an electrically insulating layer. The carrier can be formed in a multilayered fashion, wherein the carrier may include, in addition to the electrically insulating layer and the contact area, further electrically conductive regions, e.g. one or more electrically conductive layers, plated-through holes, which can extend through the electrically insulating layer, etc. In various embodiments, the carrier may include a printed circuit board, e.g. a body of a smart card module.

In various embodiments, the electrically conductive contact area may include a first side facing the carrier and a second side situated opposite the first side, and the plurality of depressions can extend from the second side as far as the first side.

In various embodiments, the electrically conductive contact area may include a first side facing the carrier and a second side situated opposite the first side, and the plurality of depressions can extend from the second side not as far as the first side.

In various embodiments, forming the electrically conductive contact area having the plurality of depressions may include forming the electrically conductive layer on the carrier, e.g. by means of placement (e.g. deposition and/or electroplating or the like), and subsequently forming the plurality of depressions (e.g. by means of etching, laser ablation or the like).

In various embodiments, forming the plurality of depressions can be carried out in such a way that the depression extends as far as the (electrically insulating) carrier. In various embodiments, forming the plurality of depressions can be stopped prior to reaching the carrier (e.g. the etching can be interrupted or the laser ablation can be stopped), with the result that the depressions do not extend as far as the (electrically insulating) carrier, rather the electrically conductive material still remains at the bottom of the depression.

In various embodiments, forming an electrically conductive contact area having a plurality of depressions may include placement (e.g. deposition and/or electroplating or the like) of the electrically conductive contact area with the plurality of depressions. To put it another way, as early as during the deposition of the electrically conductive contact area a structuring of the electrically conductive layer can be predefined, e.g. by means of a mask, such that the contact area is formed directly with the plurality of depressions.

In various embodiments, forming an electrically conductive contact area having a plurality of depressions can be carried out directly on the (electrically insulating) carrier, with the result that the plurality of depressions of the contact area formed extend from a second side of the contact area, said second side facing away from the carrier, as far as the carrier.

In various embodiments, firstly an (e.g. continuous) layer of the electrically conductive material can be formed on the carrier, and forming the electrically conductive contact area having the plurality of depressions can be carried out on the (e.g. continuous) electrically conductive layer, with the result that the depressions do not extend as far as the (electrically insulating) carrier, rather the electrically conductive material still remains at the bottom of the depression.

In various embodiments, the chip contact may include an electrically conductive material which can be more easily deformable than a material of the electrically conductive contact area at least during the contacting of the chip contact. The chip contact may include for example gold, copper or a metal alloy, e.g. a gold or copper alloy.

During the production of the pressure contacting between the chip contact and the contact area (e.g. by means of the chip and the carrier being pressed onto one another in such a way that the chip contact and the contact area come into contact with one another and the chip contact deforms, possibly by means of additionally heating at least the chip contact, e.g. to a temperature at which a solder from which the chip contact can be formed becomes deformable, e.g. a temperature in a range of approximately 120° C. to approximately 200° C.), it is thus possible to deform the chip contact on the contact area and into the depression(s) in order to form the three-dimensionally structured contact interface. In this case, the contact area can be so rigid that it does not deform or deforms only insignificantly. In various embodiments, the material of the chip contact can be more easily deformable than the contact area only at an elevated contacting temperature (e.g. in comparison with room temperature or a typical operating temperature). In that case, the chip contact (possibly together with the rest of the flip-chip device) can be heated during the contacting. By way of example, the chip contact may include a solder, for example a silver alloy solder.

In various embodiments, the contact area may include an electrically conductive material, for example at least one metal or at least one metal alloy, e.g. copper, gold, a copper alloy or a gold alloy. The contact area can be formed for example as a (structured) metal layer or as a (structured) layer stack composed of a plurality of metals or metal alloys. In various embodiments, a thickness of the contact area can be between approximately 5 μm and approximately 50 μm, e.g. between approximately 10 μm and approximately 40 μm.

In various embodiments, the chip contact and the contact area may include different materials, e.g. materials which are (e.g. plastically) deformable to different extents, wherein the chip contact may include the material having the better (higher) deformability. By way of example, if the contact area includes a usually relatively rigid copper alloy as the electrically conductive material or the material consists thereof, the chip contact may include or consist of gold, which, compared with the copper alloy, can be deformable relatively easily. By contrast, if a contact area composed of/including gold is used, for example, the chip contact may include the silver alloy solder, for example, which can be more easily deformable than the gold at least at a soldering temperature.

In various embodiments, the term contact area can denote that (area) region of the flip-chip device which consists of the plurality of depressions and the electrically conductive material arranged between the depressions. In various embodiments, an edge area region which at least partly (e.g. completely) surrounds the region having the depressions and the electrically conductive material arranged therebetween and which can be narrower than the smallest width of the chip contact can furthermore be regarded as associated with the contact area.

To put it another way, the plurality of depressions can be arranged in such a way as to fill the contact area. To put it another way, the plurality of depressions can be arranged in a manner distributed over the entire contact area, together with the electrically conductive material respectively arranged between the depressions and demarcating the respective depressions relative to one another (and, if appropriate, in various embodiments, together with the edge region composed of the electrically conductive material that overall at least partly surrounds the plurality of depressions).

A conduction region which is electrically conductively connected to the contact area, e.g. adjoins the contact area, and which has none of the depressions and is also not part of the edge region can, in various embodiments, not be part of the contact area.

In various embodiments, the contact area may include a topmost surface, which should be understood to mean a surface region which is at a maximum distance from the carrier. The plurality of depressions can be formed in the contact area in such a way that each of the depressions extends from the topmost surface in the direction of the carrier. The respective depression can extend partly or completely as far as the carrier. A depth of the depression can be between approximately 5 μm and approximately 50 μm, for example between approximately 10% and 100% of the thickness of the contact area.

In various embodiments, a smallest width of each of the depressions can be smaller than a smallest width of the chip contact.

In this case, a width of the depression should be understood to mean any distance between mutually opposite edges of the depression, wherein the distance is measured parallel to a main area of the carrier. The smallest width of the depression is that width of the depression for which the mutually opposite edges have the smallest distance. In a case where the mutually opposite edges of the depression have the same distance everywhere (e.g. in the case of a depression having a circular cross section), the width of the depression is also simultaneously the smallest width.

Correspondingly, a width of the chip contact should be understood to mean any distance between mutually opposite edges of the chip contact, wherein the distance is measured parallel to a main area of the chip. The smallest width of the chip contact is that width of the chip contact for which the mutually opposite edges have the smallest distance. In a case where the mutually opposite edges of the chip contact have the same distance everywhere (e.g. in the case of a chip contact having a circular cross section), the width of the chip contact is also simultaneously the smallest width.

Since, in each of the depressions, the smallest width is smaller than the smallest width of the chip contact, it is possible, in various embodiments, to prevent the chip contact from being able to be arranged in the depression completely, without producing an electrically conductive contact.

In various embodiments, each of the distances between adjacent edges of adjacent depressions can be smaller than the smallest width of the chip contact. To put it another way, a region of the topmost surface which is situated between respectively two adjacent depressions can have a smaller width than the smallest width of the chip contact. It is thus possible to prevent the chip contact from being arranged only on the topmost surface, which would lead to a two-dimensional contact interface formed in a plane. By virtue of the fact that the region between two adjacent depressions is narrower than the chip contact, irrespective of where on the contact area the chip contact is arranged, the chip contact is always pressed into at least one of the depressions at least partly during the production of the press contact, thus resulting in the three-dimensional structure of the contact interface.

In various embodiments, the contact area can be larger than a cross-sectional area of the chip contact parallel to a main area of the chip. In a case where the chip contact has a shape that tapers toward the chip or away from the chip, the contact area can be larger than the largest cross-sectional area of the chip contact parallel to the main area of the chip.

Thus, in various embodiments, a relatively large positioning tolerance can be made possible since, given the presence of the contact area which is larger than the cross-sectional area of the chip contact, the chip contact can be reliably connectable to the contact area even in the event of a deviation from its nominal position.

In various embodiments, the contact area can be between approximately 1.1 and approximately ten times the size of the cross-sectional area of the chip contact, e.g. between two and five times the size thereof.

In various embodiments, the contact area can be enlarged uniformly in every direction, compared with the cross-sectional area of the chip contact. By way of example, in the case of a chip contact having a round or substantially round cross-sectional area, the contact area can be round or substantially round with a larger diameter, or, in the case of a chip contact having an (e.g. substantially) square cross section, the contact area can be (e.g. substantially) square, with a larger edge length. In the case of a chip contact having an (e.g. substantially) rectangular cross section, the contact area can be formed as a larger rectangle having the same ratio of the edge lengths, wherein the contact area can be formed on the carrier in such a way that the longer edge extends in a direction in which a longer edge of the rectangular chip contact also extends.

In various embodiments, the contact area can be enlarged non-uniformly in different directions, compared with the cross-sectional area of the chip contact. By way of example, in the case of a chip contact having a round or substantially round cross-sectional area, the contact area can be elliptic or substantially elliptic, with axes that are longer than the diameter of the chip contact, or, in the case of a chip contact having an (e.g. substantially) square cross section, the contact area can be (e.g. substantially) rectangular, with edge lengths that are greater than the edge length of the chip contact. In various embodiments, the contact area can be arranged on the carrier in such a way that a direction in which the contact area is enlarged to a greater extent (e.g. the long axis of the ellipse or of the rectangle) extends in a direction in which greater positioning uncertainty is expected (e.g. in a case where a plurality of chip contacts are present on the chip, which chip contacts are positioned simultaneously).

In various embodiments, the plurality of depressions can be formed as a regular pattern in the contact area.

A regular pattern should be understood to mean that the plurality of depressions can be defined as consisting of a plurality of subgroups including a plurality of depressions, wherein in each of the subgroups the plurality of depressions are configured with a subgroup configuration, e.g. with regard to their shape, size, alignment and distances with respect to one another, and wherein the subgroup configuration is the same or substantially the same for each of the subgroups. One example of a regular pattern may be a two-dimensionally matrix-shaped arrangement of the depressions, wherein the depressions can have e.g. a polygonal (e.g. rectangular or square), a round or an elliptic cross section (such that for example a lattice-shaped structure of the electrically conductive material of the contact area can result). Another example of a regular pattern may be a parallel arrangement of (e.g. elongated) depressions, which can lead to a comb-like structure of the electrically conductive material of the contact area.

In various embodiments, the plurality of depressions in the contact area can be formed as tubular depressions, wherein a tubular depression should be understood to mean that a diameter of the depression is significantly smaller than a depth of the depression. By way of example, a ratio of diameter to depth of the tubular depression can be in a range of approximately 1:3 to approximately 1:50, e.g. of approximately 1:10 to approximately 1:25. In various embodiments, the tubular depression can be produced by means of a laser, e.g. by means of laser ablation.

In various embodiments, the flip-chip device can furthermore include an electrically insulating adhesion medium, which can be arranged between the chip and the carrier, for securing the chip to the carrier. The adhesion medium used can be an adhesion medium that is usually used for this purpose, e.g. an epoxy adhesive. In various embodiments, the adhesion medium can be arranged between the carrier and the chip before the chip contact and the contact area are pressed against one another, such that during pressing an excess part of the adhesion medium can be forced out of a space between the chip and the carrier, or, in various embodiments, the adhesion medium can be arranged between the chip and the carrier after the production of the contact between chip contact and contact area (and, if appropriate, after cooling of the chip contact, the contact area, the chip and/or the carrier if heating is employed for contacting).

In various embodiments, the flip-chip device can furthermore include at least one further electrically conductive chip contact including the material which is deformable at least during the contacting of the chip contact, and at least one further electrically conductive contact area for contacting the at least one further chip contact, wherein the chip contact and the at least one further chip contact can be arranged on the chip and the contact area and the at least one further contact area can be arranged on the carrier in such a way that respectively one of the chip contacts can be provided for contacting one of the contact areas, wherein the at least one further contact area may include a plurality of further depressions, and wherein each of the distances between adjacent further depressions of the plurality of further depressions can be smaller than a smallest width of the further chip contact. That is to say that the flip-chip device may include a plurality of contact areas which are formed on the carrier and which can be formed in a manner as described above for various embodiments, and a plurality of chip contacts which can be arranged on the same side of the chip, wherein the chip contacts and the contact areas can be arranged in each case such that respectively one of the contact areas is contacted by one of the chip contacts.

In various embodiments, a flip-chip device is provided. The flip-chip device may include a chip having an electrically conductive chip contact and a carrier having an electrically conductive contact area for contacting the chip contact, wherein the chip contact may include a material which can be at least just as easily deformable as a material of the electrically conductive contact area at least during the contacting of the chip contact, wherein the contact area may include a plurality of depressions, wherein a smallest width of each of the depressions can be smaller than a smallest width of the chip contact, and wherein each of the distances between adjacent edges of adjacent depressions can be smaller than the smallest width of the chip contact.

In various embodiments, the material of the chip contact can be more easily deformable than the material of the electrically conductive contact area.

In various embodiments, the contact area can be larger than a cross-sectional area of the chip contact parallel to a main area of the chip.

In various embodiments, the plurality of depressions can be arranged in such a way as to fill the contact area.

In various embodiments, the plurality of depressions can be arranged in the contact area in such a way that the contact area is structured in a lattice-shaped fashion.

In various embodiments, the plurality of depressions can be arranged in the contact area in such a way that the contact area is structured in a comb-like fashion.

In various embodiments, the plurality of depressions in the contact area can be formed as tubular depressions.

In various embodiments, the electrically conductive contact area may include a first side facing the carrier and a second side situated opposite the first side, and the plurality of depressions can extend from the second side as far as the first side.

In various embodiments, the electrically conductive contact area may include a first side facing the carrier and a second side situated opposite the first side, and the plurality of depressions can extend from the second side not as far as the first side.

In various embodiments, the flip-chip device can furthermore include an electrically insulating adhesion medium, which can be arranged between the chip and the carrier, for securing the chip to the carrier.

In various embodiments, the flip-chip device can furthermore include at least one further electrically conductive chip contact including the material which is deformable at least during the contacting of the chip contact, and at least one further electrically conductive contact area for contacting the at least one further chip contact, wherein the chip contact and the at least one further chip contact can be arranged on the chip and the contact area and the at least one further contact area can be arranged on the carrier in such a way that respectively one of the chip contacts can be provided for contacting one of the contact areas, wherein the at least one further contact area may include a plurality of further depressions, and wherein each of the distances between adjacent further depressions of the plurality of further depressions can be smaller than a smallest width of the further chip contact.

In various embodiments, the plurality of depressions can be formed as a regular pattern in the contact area.

In various embodiments, a method for forming a flip-chip device is provided. The method may include providing a chip having an electrically conductive chip contact, and forming an electrically conductive contact area having a plurality of depressions on a carrier, wherein the contact area is configured for contacting the chip contact. In this case, the chip contact may include a material which can be deformable at least during the contacting of the chip contact, a smallest width of each of the depressions can be smaller than a smallest width of the chip contact, and each of the distances between adjacent edges of adjacent depressions can be smaller than a smallest width of the chip contact.

In various embodiments, the material of the chip contact can be at least just as easily deformable as the material of the electrically conductive contact area.

In various embodiments, the material of the chip contact can be more easily deformable than the material of the electrically conductive contact area.

In various embodiments, forming the electrically conductive contact area having the plurality of depressions may include forming an electrically conductive layer and subsequently forming the plurality of depressions.

In various embodiments, forming the plurality of depressions may include at least one etching process.

In various embodiments, forming the plurality of depressions may include forming tubular depressions by means of a laser.

In various embodiments, forming an electrically conductive contact area having a plurality of depressions may include depositing the electrically conductive contact area with the plurality of depressions.

In various embodiments, the contact area can be structured in a lattice- or comb-like fashion.

In various embodiments, the method can furthermore include connecting the chip contact to the contact area by means of pressing the chip and the carrier onto one another in such a way that the chip contact and the contact area come into contact with one another and the chip contact deforms.

In various embodiments, the connecting can furthermore include heating the chip contact.

In various embodiments, the method can furthermore include arranging an electrically insulating adhesion medium between the chip and the carrier.

Some of the embodiments are described in connection with devices, and some of the embodiments are described in connection with methods. Further advantageous configurations of the method emerge from the description of the device, and vice versa.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A flip-chip device, comprising:
a chip having an electrically conductive chip contact; and
a carrier having an electrically conductive contact area for contacting the chip contact;
wherein the chip contact comprises a material which is at least as deformable as a material of the electrically conductive contact area at least at a soldering temperature;
wherein the contact area comprises a plurality of depressions;
wherein a smallest width of each of the depressions is smaller than a smallest width of the chip contact;
wherein each of the distances between adjacent edges of adjacent depressions is smaller than the smallest width of the chip contact;
wherein the plurality of depressions in the contact area are formed as tubular depressions, and
wherein a ratio of diameter to depth of the tubular depressions is in a range of 1:3 to 1:50.

2. The flip-chip device of claim 1,
wherein the contact area is larger than a cross-sectional area of the chip contact parallel to a main area of the chip.

3. The flip-chip device of claim 1,
wherein the plurality of depressions are arranged in such a way as to fill the contact area.

4. The flip-chip device of claim 1,
wherein the electrically conductive contact area comprises a first side facing the carrier and a second side situated opposite the first side; and
wherein at least one of the plurality of depressions extends from the second side as far as the first side.

5. The flip-chip device of claim 1,
wherein the electrically conductive contact area comprises a first side facing the carrier and a second side situated opposite the first side; and
wherein at least one of the plurality of depressions extends from the second side not as far as the first side.

6. The flip-chip device of claim 1, further comprising:
an electrically insulating adhesion medium, which is arranged between the chip and the carrier, for securing the chip to the carrier.

7. The flip-chip device of claim 1, further comprising:
at least one further electrically conductive chip contact comprising the material of the chip contact, which is deformable at least at a soldering temperature;
at least one further electrically conductive contact area for contacting the at least one further chip contact;
wherein the chip contact and the at least one further chip contact are arranged on the chip and the contact area and the at least one further contact area are arranged on the carrier in such a way that respectively one of the chip contacts is provided for contacting one of the contact areas;
wherein the at least one further contact area comprises a plurality of further depressions; and
wherein each of the distances between adjacent further depressions of the plurality of further depressions is smaller than a smallest width of the further chip contact.

8. The flip-chip device of claim 1,
wherein the plurality of depressions are formed as a regular pattern in the contact area.

9. A method for forming a flip-chip device, the method comprising:
providing a chip having an electrically conductive chip contact;
forming an electrically conductive contact area having a plurality of depressions on a carrier, wherein
the contact area is configured for contacting the chip contact;
a smallest width of each of the depressions is smaller than a smallest width of the chip contact;
each of the distances between adjacent edges of adjacent depressions is smaller than a smallest width of the chip contact;
the plurality of depressions in the contact area are formed as tubular depressions; and
a ratio of diameter to depth of the tubular depressions is in a range of 1:3 to 1:50; and
contacting the chip contact to the electrically conductive contact area, during which, a material of the chip contact is at least as deformable as a material of the electrically conductive contact area.

10. The method of claim 9,
wherein forming the electrically conductive contact area having the plurality of depressions comprises forming an electrically conductive layer and subsequently forming the plurality of depressions.

11. The method of claim 10,
wherein forming the plurality of depressions comprises at least one etching process.

12. The method of claim 10,
wherein forming the plurality of depressions comprises forming the tubular depressions by a laser.

13. The method of claim 10,
wherein forming an electrically conductive contact area having a plurality of depressions comprises depositing the electrically conductive contact area with the plurality of depressions.

14. The method of claim 10,
wherein forming an electrically conductive contact area having a plurality of depressions comprises depositing the electrically conductive contact area with the plurality of depressions in such a way that the contact area is formed directly with the plurality of depressions.

15. The method of claim 9:
contacting the chip contact to the electrically conductive contact area by of pressing the chip and the carrier onto one another in such a way that the chip contact and the electrically conductive contact area come into contact with one another and the chip contact deforms to connect the chip contact and the electrically conductive contact area.

16. The method of claim 15,
wherein the contacting further comprises heating the chip contact.

17. The method of claim 9, further comprising:
arranging an electrically insulating adhesion medium between the chip and the carrier.
